(19) United States
(12) Patent Application Publication
(10) Pub. No.: US 2010/0182168 A1
(43) Pub. Date: Jul. 22, 2010

(54) METHOD OF PROCESSING DATA GENERATED BY A USER INPUT DEVICE FOR INDICATING POSITIONS

(75) Inventors: Sander Bernard Francis Van De Wijdeven, Eindhoven (NL); Gerrit Hollemans, Eindhoven (NL); Maurice Groten, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/667,057

(22) PCT Filed: Jun. 26, 2008
(86) PCT No.: PCT/IB08/52576

§ 371 Date: Dec. 29, 2009

(30) Foreign Application Priority Data
Jul. 2, 2007 (EP) 07111492.0

(51) Int. Cl. H03K 17/94

(52) U.S. Cl. 341/20

(57) ABSTRACT

A user input device for indicating positions includes a transmitter arrangement (4,5) for directing wave energy across a surface (1) in at least two directions, a sensor arrangement (6,7) at a periphery of the surface (1) for detecting wave energy received across the surface within any of a plurality of fields of view, at least some of which are mutually intersecting, and a processing device (12) for determining potential positions of objects (2,3) placed on the surface (1), based on signals from the sensor arrangement (6,7) indicating intersecting at least partially blocked fields of view. A method of processing data generated by the user input device includes receiving information (19) from the processing device (12) representative of at least one set of potential positions of a plurality of objects (2,3) and intersecting the received information (19) with information (21) representing a set of pre-determined

### FIELD OF THE INVENTION

The invention relates to a method of processing data generated by a user input device for indicating positions, a system for processing data generated by a user input device for indicating positions, and an apparatus for obtaining user input identifying positions in two dimensions.

The invention also relates to a method of providing data for indicating positions in a user input device, a user input device for indicating positions, and a computer programme.

### BACKGROUND OF THE INVENTION

WO 2006/095320 discloses an apparatus for detecting the location, size and shape of an object, or multiple objects, placed on a plane within the touch sensor boundaries of a touch screen. The apparatus includes a plurality of light transmitters and sensors arranged in an alternating pattern on the periphery of the touch screen. In accordance with an illustrative embodiment, detection of the position, shape and size of one or more objects interacting with the touch screen display is performed continuously over multiple cycles of operation. In the illustrative embodiment, each of the light transmitters illuminates in a pre-determined sequence constituting a single cycle of operation which is repeated over multiple cycles of operation. During each cycle of operation in an operational mode, minimum and maximum area estimates are made for the detected objects. The estimates are stored in a data repository for later recall in detecting an object boundary area. Upon completing a single cycle of operation, the minimum and maximum area estimates are retrieved from the data repository and combined in a certain manner to determine an object boundary area for each detected object in the plane of the touch screen.

A problem of the known system is that it is relatively complicated and thus expensive to produce. To detect multiple objects, the light transmitters must be distributed along the entire length of the perimeter, more or less evenly, and activated in turn. The shadows cast when one of the light transmitters is on must be registered in association with information indicating which one of the light transmitters was on, for later processing. The known system thus requires an apparatus for control of the light transmitters as well as a relatively sophisticated arrangement for processing the signals obtained in the course of a cycle, making it relatively complex.

### SUMMARY OF THE INVENTION

It is an object of the invention to provide a method, system, apparatus and computer programme of the types mentioned in the opening paragraphs that are suitable for use in conjunction with a relatively simple input device and allow the positions of multiple objects placed on the surface to be determined in at least some configurations.

This object is achieved by the method of processing data generated by a user input device for indicating positions, which user input device includes:

a transmitter arrangement for directing wave energy across a surface in at least two directions,

a sensor arrangement at a periphery of the surface for detecting wave energy received across the surface within any of a plurality of fields of view, at least some of which are mutually intersecting, and

a processing device for determining potential positions of objects placed on the surface, based on signals from the sensor arrangement indicating intersecting at least partially blocked fields of view, which method includes:

receiving information from the processing device representative of at least one set of potential positions of a plurality of objects and

intersecting the received information with information representing a set of pre-determined positions.

By determining an intersection between a set of pre-determined positions and the totality of the set(s) of potential positions, it is possible to reduce the number of potential positions to a number close to or equal to the number of objects placed on the surface, even if the processing device produces more than one set of potential positions or a set of potential positions with more members than there are objects placed on the surface. Thus, the method is able to function in conjunction with a relatively simple input device that generates ambiguities, in particular when one object is, or could be, in the shadow of another object. Such input devices typically include those in which all fields of view are oriented in parallel to one of two orthogonal directions and the wave energy is directed along them in only one sense. Such input devices do not require alternating activation of light sources. Even in embodiments in which light sources are distributed around the entire periphery of the surface, the signal processing requirements of the input device are still relatively low. For example, the positions of multiple objects can be inferred merely by evaluating for each of multiple transmitters whether a signal from a transmitter at a particular location is picked up at an opposite location across the surface by the sensor arrangement, instead of evaluating the entire shadow pattern around the perimeter of the surface.

An embodiment, wherein the information received from the processing device is representative of a plurality of sets of positions, each indicating a combination of positions of a respective number of objects resulting in the at least partial blockage of the intersecting fields of view indicated by the signals, includes:

intersecting the information representing each of the plurality of sets with the information representing the set of predetermined positions to retain those sets of potential positions completely comprised in the sets of pre-determined positions.

An effect of this embodiment is that knowledge of how many objects are actually on the surface can already be contained in the sizes of the plurality of sets of positions. A separation of the functions of determining potential positions and determining the valid set of potential positions on the basis of the set of pre-determined positions can be achieved with relatively little passing of information between the entities performing the functions.

An embodiment includes, if no set of potential positions is completely comprised in the set of pre-determined positions, causing an output device to provide an appropriate output to a user.

An effect is that applications to be provided with data corresponding to the user input are shielded from invalid input.

An embodiment includes, if more than a pre-determined number of all potential positions is comprised in the set of pre-determined positions, returning a set of potential positions comprised in the set of pre-determined positions in dependence on at least one of:
(a) an evaluation of a set of pre-determined rules for determining permitted combinations of positions and
(b) a set of earlier actual positions stored in memory,
to determine a set of current actual positions.

An effect is to reduce the likelihood of applications receiving the user input having to resolve ambiguities or evaluate results obtained with different possible sets of positions in order to determine retrospectively which one must have been the right one.

A variant includes storing the set of current actual positions in memory.

An effect is to allow ambiguities to be resolved by assessing the evolution of object placement in time. In particular where the user input device is being used to implement a game, combinations of positions that violate the game rules for moving objects can be dismissed as unlikely.

In an embodiment, a visual indication of sections of the surface corresponding to the pre-determined positions on the surface is caused to be provided.

An effect is that a user is provided with an aid to avoid placing objects at positions in which they are not or cannot be detected because they are not comprised in the set of pre-determined positions.

According to another aspect, the system for processing data generated by a user device for indicating positions according to the invention includes:

an interface for receiving information from the processing device representative of at least one set of potential positions of a plurality of objects and

is operative to intersect the received information with information representing a set of pre-determined positions.

In an embodiment, the system is operative to carry out a method according to the invention.

In an embodiment, the processing device for determining potential positions of objects is implemented in hardware.

An effect is to allow fast determination of sets of potential object positions. The method of processing data generated by the user input can be implemented in software running on a general-purpose processor. For this reason, the method of determining actual object positions can be adapted to the specific application of the user input device. On the other hand, the determination of sets of potential object positions is needed for all applications of the user input device. Therefore, it can be implemented efficiently in hardware.

According to another aspect, the apparatus for obtaining user input identifying positions in two dimensions according to the invention includes a data processing system, configured to determine at least one set of potential positions of objects placed on the surface, based on signals from the sensor arrangement indicating intersecting at least partially blocked fields of view, to retrieve information representative of a set of pre-determined positions and to intersect information representative of each set of potential positions with information representing a set of pre-determined positions.

In an embodiment, the data processing system is configured to perform a method according to the invention.

In an embodiment, the transmitter arrangement includes a first set of transmitters for directing wave energy along contiguous parallel lines across the surface, positioned relative to the surface such that each of the first set of transmitters transmits wave energy in the same direction along the contiguous parallel lines.

An effect is that objects placed on the surface cast shadows even when all of the first set of transmitters is activated. This allows the use of simpler systems for activating the transmitter arrangement for directing wave energy across a surface in at least two directions.

An embodiment includes:

first and second sets of transmitters and

first and second sets of receivers, the first set of transmitters being arranged to direct wave energy along parallel lines in a first direction across the surface and the second set of transmitters being arranged to direct wave energy along parallel lines in a second direction across the surface,

wherein the transmitters and receivers are positioned such that only the transmitters of the first of the first and second sets are within the field of view of the first set of receivers.

An effect is that the first and second sets of transmitters can be activated simultaneously, since the first set of receivers is attuned to only one set of transmitters. That is to say that the first set of receivers is operative to detect blocked lines of sight parallel to only one direction. Thus, an effective determination of positions can be carried out without sequential activation of transmitters.

According to another aspect, the method of providing data for indicating positions in a user input device according to the invention includes:

causing a transmitter arrangement to direct wave energy across a surface in at least two directions,

detecting, at a sensor arrangement at a periphery of the surface, wave energy received across the surface within any of a plurality of fields of view, at least some of which are mutually intersecting, and, based on signals from the sensor arrangement indicating intersecting at least partially blocked fields of view, determining a plurality of sets of positions of objects placed on the surface, each set a combination of positions of a respective number of objects resulting in the at least partial blockage of the intersecting fields of view indicated by the signals, wherein information representative of the sets of potential positions is provided to a system according to the invention.

According to another aspect, in the user input device according to the invention, the processing device is configured, based on the signals from the sensor arrangement, to determine a plurality of sets of positions of objects placed on the surface, each set a combination of positions of a respective number of objects resulting in the at least partial blockage of the intersecting fields of view indicated by the signals, and the input device includes an interface for providing information representative of the sets of potential positions to a system according to the invention.

According to another aspect, the computer programme according to the invention includes a set of instructions capable, when incorporated in a machine-readable medium, of causing a system having information processing capabilities to perform a method according to the invention.

### BRIEF DESCRIPTION OF THE DRAWINGS

The invention will now be explained in further detail with reference to the accompanying drawings, in which:

FIG. 1 is a schematic top plan view of a user input device, showing the transmitter arrangement and sensor arrangement, as well as the surface on which objects can be placed;

FIG. 2 is a block diagram of an embodiment of an apparatus for obtaining user input including such an input device; and

FIG. 3 is a flow chart of a method of processing data generated by the user input device.

### DETAILED DESCRIPTION

The user input device comprises a playing surface 1 on which objects can be placed. First and second objects 2,3 are illustrated as an example. It is observed that the methods outlined herein are not restricted to inanimate objects, but also applicable to body parts of the user, such as fingers. In particular in that case, the objects of which the position is detected need not be placed on the playing surface 1 in touching relationship. An object's position in two dimensions in a plane parallel to the playing surface 1 can also be detected if it is positioned hovering slightly above the playing surface 1.

In the illustrated embodiment, the playing surface 1 is rectangular in shape. In other embodiments, it may be square or have another shape. The set of all possible positions is preferably at least connected, more preferably convex and simply connected.

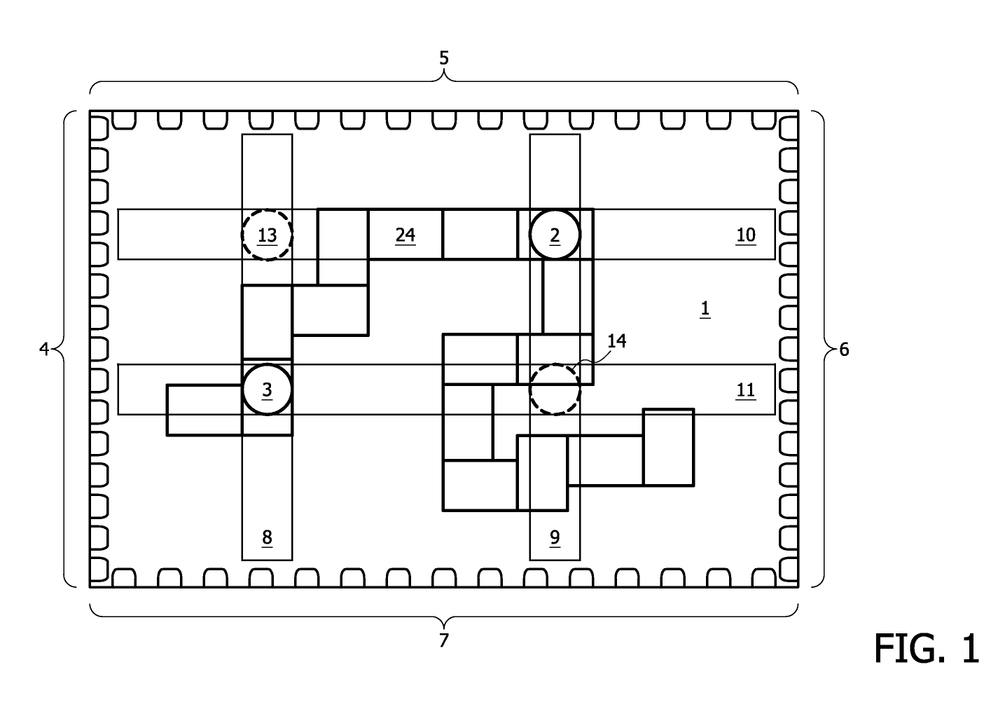

The input device includes a transmitter arrangement for directing wave energy across the playing surface along two mutually perpendicular sets of parallel lines. In the illustrated embodiment, a first set 4 of LEDs (Light-Emitting Diodes) is arranged along one of two shorter sides of the rectangular playing surface 1. There are no LEDs along the opposite shorter side. A second set 5 of LEDs is arranged along one of two longer sides of the rectangular playing surface 1. There are no LEDs along the other of the two longer sides. Thus, beams of light are emitted in parallel to the shorter edges only in one direction (from top to bottom in FIG. 1), as are beams of light emitted in parallel to the longer edges. The first and second sets 4,5 of LEDs are arranged in rows in parallel to the respective edges along which they are provided. It is not essential that the rows of first and second sets 4,5 of LEDs be parallel to the edges along which they are provided, nor is it necessary that they direct light in mutually orthogonal directions. The beams of light should intersect and the whole playing surface 1 should be covered.

Each of the LEDs is arranged to emit a relatively narrow beam of light, for example in the infrared range of the spectrum, across the playing surface 1. In other embodiments, at least some of the LEDs may emit light in a narrow cone across the playing surface 1. In any case, the light is directed, rather than diffuse. In other embodiments, a set of different light sources may be used. In yet another embodiment, a single distributed light source may be used, or a single light source in combination with a suitable waveguide and/or arrangement for reflecting light across the playing surface 1.

The input device further includes a receiver arrangement including a first set 6 of photodetectors arranged in a row parallel to that one of the shorter sides opposite the shorter side along which the first set 4 of LEDs is arranged. A second set 7 of photodetectors is arranged along one of the longer sides of the playing surface 1, opposite the longer side along which the second set 5 of LEDs is arranged. Each of the photodetectors is arranged to detect light received across the playing surface 1 within a field of view with a relatively small angle, or even only generally along a line of sight. The respective angles are small enough, and the placement of the first and second sets 6,7 of photodetectors and first and second sets 4,5 of LEDs is such that only the LEDs of the first set 4 are within the field of view of the first set 6 of photodetectors and only the LEDs of the second set 5 are within the field of view of the second set 7 of photodetectors.

In operation, the input device first goes through a calibration phase to determine the light intensity levels sensed by the photodetectors in the absence of any objects, when the LEDs are activated. The calibration phase is not essential, but may lead to more accurate determinations of blocked fields of view. In addition, it fulfils a diagnostic purpose, allowing defect LEDs in the first and second sets 4,5 and/or faulty photodetectors in the first and second sets 6,7 to be detected.

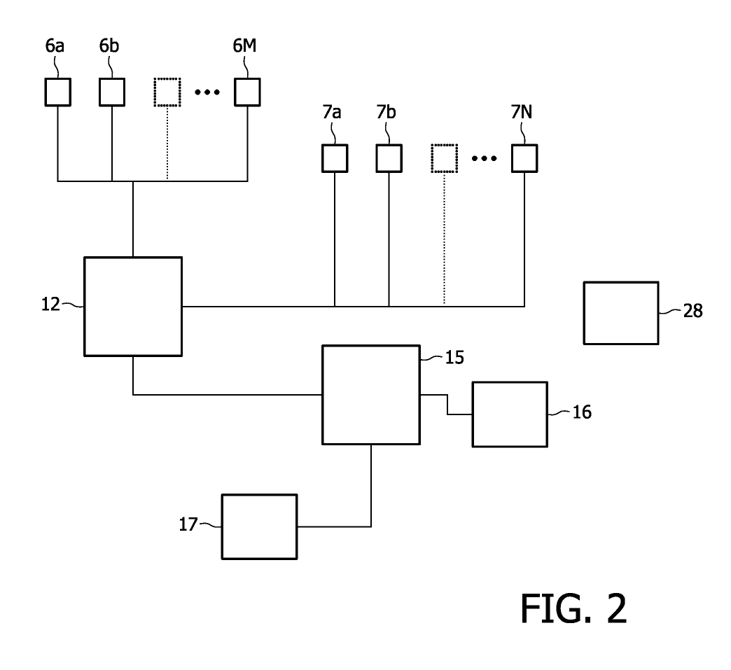

The positions of the first and second objects 2,3 are determined by analyzing shadows 8-11 cast by them as they block light within mutually intersecting lines of sight of the first and second sets 6,7 of photodetectors. To this end, a signal processing device 12 (FIG. 2) evaluates signals received from the first and second sets 6,7 of photodetectors by comparing them to background levels obtained in the calibration phase. The signal processing device 12 may be implemented in hardware, e.g. as an Application-Specific Integrated Circuit in combination with appropriate input stages for connection to the first and second sets 6,7 of photodetectors. The positions are determined by triangulation.

As a consequence of the fact that light beams parallel to the long edges of the playing surface are only emitted in one direction, as are light beams parallel to the short edges, triangulation will give rise to ambiguities. The first and second objects 2,3 could also be positioned at the positions of first and second “phantom objects” 13,14 (FIG. 1). For ease of reference, the position of the first phantom object 13 will be labeled “a”, that of the first object 2 labeled “b”, that of the second phantom object 14 labeled “c” and that of the second object 3 labeled “d”. The sets of potential positions giving rise to the illustrated shadows 8-11 are: {a,c}, {d,b}, {a,b,c}, {a,c,d}, {b,c,d} and {a,b,c,d}.

To resolve resulting ambiguities, the illustrated apparatus for obtaining user input includes a processor 15 and memory 16, arranged to execute software encoding applications and stored in a data storage device 17. At least one of the applications includes instructions enabling the processor 15 to intersect information representative of sets of potential positions received from the signal processing device 12 with information representing a set of pre-determined positions.

It is observed that the sets of potential positions correspond only to sets of positions that would actually give rise to the observed blockages of the intersecting fields of view of the first and second sets 6,7 of photodetectors. The combination {a,b}, for example, is not possible, because it is not commensurate with the existence of two shadows 11,12 parallel to the long edges of the playing surface 1. In one embodiment, the signal processing device 12 is also provided with data representative of the number of objects placed on the playing surface 1. In this embodiment, the signal processing device 12 would only output information representative of the sets {a,c} and {d,b} in the illustrated example. In another embodiment, knowledge of the number of objects on the playing surface 1 is embodied in the application executed by the data processor 15.

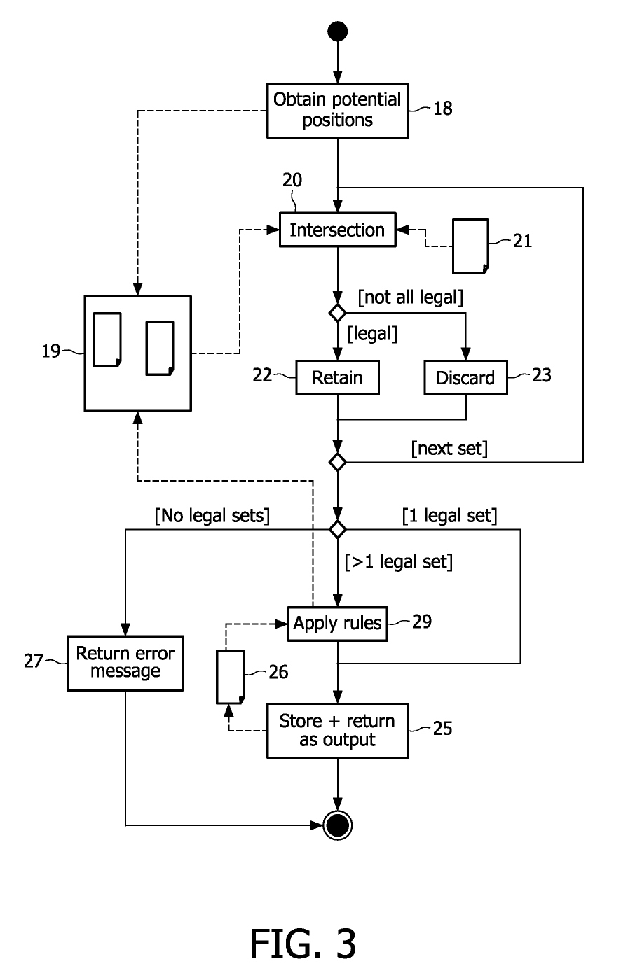

Turning to FIG. 3, the application for processing the data representative of the sets of potential positions of the first and second objects 2,3 proceeds as follows.

In a first step 18, a set 19 of information representative of the sets of potential positions is received from the signal processing device 12. This set 19 of information is intersected (step 20) with information 21 representative of a set of pre-determined, “legal” positions, one set of potential positions at a time. If the set of potential positions is completely contained within the set of legal positions, then the set of potential positions is retained (step 22). Otherwise, it is discarded (step 23) from the total set 19 received from the signal processing device 12.

The set of legal positions is comprised of positions corresponding to visually distinct sections 24 of the playing surface 1. Their positions are dictated by the rules of the application for which the object positions provide input, e.g. a game. In an embodiment, a visual indication of these sections 24 is projected on or through the playing surface 1 in accordance with the set 21 of information representative of the legal positions. Thus, an effect of implementing the method of FIG. 3 in software is that the set 21 of information representative of the legal positions can vary with the application being run. The input device is therefore useable with a range of applications. One implementation of such an embodiment involves the use of an input device in which the playing surface 1 comprises the surface of a touch screen.

In the illustrated embodiment, and assuming that only the sets {a,c} and {d,b} are received in the first step 18, the set {a,c} will be discarded, so that only one set of legal positions is left. This is the hallmark of a well-designed game: the sections 24 indicated on the playing surface 1 that correspond to the set of legal positions are distributed such that none of a pre-determined set of combinations of the legal positions can give rise to the same signal pattern from the sensor arrangement indicative of at least partial blockage of the fields of view of the first and second sets 6,7 of photodetectors. In the situation illustrated in FIG. 1, the one remaining set {d,b} of positions is determined to be the current set of actual positions, returned (step 25) as output to the routines in the application that actually implement the game, and stored in an array 26 in memory 16.

It can also happen that there are no sets of potential positions left after the step 20 has been carried out on the whole set 19 of information received from the signal processing device 12. In this case, an error message is caused to be displayed (step 27) on a display device 28. Generally, the error message will inform the user that one of the objects 2,3 has been misplaced.

It can also happen that the game is not so well-designed that none of a pre-determined set of combinations of the legal positions can give rise to the same signal pattern from the sensor arrangement indicative of at least partial blockage of the fields of view of the first and second sets 6,7 of photodetectors. Also, in some embodiments, the signal processing device 12 has no access to information representative of the number of objects placed on the playing surface 1. In particular for such situations and embodiments, the method of FIG. 3 includes a further step 29 of, if more than a pre-determined number of all potential positions is comprised in the set of pre-determined positions, evaluating a set of pre-determined rules to determine a set of current actual positions. In this step 29, knowledge of the game rules governing the number of objects in play can be used to discard sets of potential positions from the total set 19 of information based on the number of potential positions comprised therein. Also, rules governing the “legal” moves of objects from one round of the game to the next may disqualify some sets of potential positions, based on the set of actual positions of the previous round represented by the array 26 stored in memory 16. In this manner, it can be ensured that only one set of potential positions is determined to be the next set of actual positions. Only information representative of this one next set of actual positions is processed by the parts of the application that implement the game.

It should be noted that the embodiments described above illustrate rather than limit the invention, and that those skilled in the art will be able to design many alternative embodiments without departing from the scope of the appended claims. In the claims, any reference signs placed between parentheses shall not be construed as limiting the claim. Use of the verb “comprise” and its conjugations does not exclude the presence of elements or steps other than those stated in a claim. The article “a” or “an” preceding an element does not exclude the presence of a plurality of such elements. The invention may be implemented by means of hardware comprising several distinct elements, and by means of a suitably programmed computer. In the device claim enumerating several means, several of these means may be embodied by one and the same item of hardware. The mere fact that certain measures are recited in mutually different dependent claims does not indicate that a combination of these measures cannot be used to advantage.

1. Method of processing data generated by a user input device for indicating positions, which user input device includes:
a transmitter arrangement (4,5) for directing wave energy across a surface (1) in at least two directions,
a sensor arrangement (6,7) at a periphery of the surface (1) for detecting wave energy received across the surface within any of a plurality of fields of view, at least some of which are mutually intersecting, and
a processing device (12) for determining potential positions of objects (2,3) placed on the surface (1), based on signals from the sensor arrangement (6,7) indicating intersecting at least partially blocked fields of view, which method includes:
receiving information (19) from the processing device (12) representative of at least one set of potential positions of a plurality of objects (2,3) and
intersecting the received information (19) with information (21) representing a set of pre-determined positions.

2. Method according to claim 1, wherein the information (19) received from the processing device (12) is representative of a plurality of sets of positions, each indicating a combination of positions of a respective number of objects (2,3) resulting in the at least partial blockage of the intersecting fields of view indicated by the signals, including intersecting the information (19) representing each of the plurality of sets with the information (21) representing the set of predetermined positions to retain those sets of potential positions completely comprised in the sets of pre-determined positions.

3. Method according to claim 1, including, if no set of potential positions is completely comprised in the set of pre-determined positions, causing an output device (28) to provide an appropriate output to a user.

4. Method according to claim 1, including, if more than a pre-determined number of all potential positions is comprised in the set of pre-determined positions, returning a set of potential positions comprised in the set of pre-determined positions in dependence on at least one of:
(a) an evaluation of a set of pre-determined rules for determining permitted combinations of positions and
(b) a set (26) of earlier actual positions stored in memory (16,17),
to determine a set of current actual positions.

5. Method according to claim 4, including storing the set of current actual positions in memory (16,17).

6. Method according to claim 1, wherein a visual indication of sections (24) of the surface (1) corresponding to the pre-determined positions on the surface (1) is caused to be provided.

7. System for processing data generated by a user input device for indicating positions, which user input device includes:
a transmitter arrangement (4,5) for directing wave energy across a surface (1) in at least two directions,
a sensor arrangement (6,7) at a periphery of the surface (1) for detecting wave energy received across the surface (1) within any of a plurality of fields of view, at least some of which are mutually intersecting; and
a processing device (12) for determining potential positions of objects (2,3) placed on the surface (1), based on signals from the sensor arrangement (6,7) indicating intersecting at least partially blocked fields of view, wherein the system includes:
an interface for receiving information (19) from the processing device (12) representative of at least one set of potential positions of a plurality of objects (2,3) and
wherein the system is operative to intersect the received information (19) with information (21) representing a set of pre-determined positions.

8. System for processing data generated by a user input device for indicating positions, which user input device includes:
a transmitter arrangement (4,5) for directing wave energy across a surface (1) in at least two directions,
a sensor arrangement (6,7) at a periphery of the surface (1) for detecting wave energy received across the surface (1) within any of a plurality of fields of view, at least some of which are mutually intersecting; and
a processing device (12) for determining potential positions of objects (2,3) place on the surface (1), based on signals from the sensor arrangement (6,7) indicating intersecting at least partially blocked fields of view, wherein the system includes:
an interface for receiving information (19) from the processing device (12) representative of at least one set of potential positions of a plurality of objects (2,3) and
wherein the system is operative to intersect the received information (19) with information (21) representing a set of pre-determined positions, operative to carry out a method according to claim 1.

9. System according to claim 8, wherein the processing device (12) for determining potential positions of objects is implemented in hardware.

10. Apparatus for obtaining user input identifying positions in two dimensions, including:
a transmitter arrangement (4,5) for directing wave energy across a surface (1) in at least two directions,
a sensor arrangement (6,7) at a periphery of the surface (1) for detecting wave energy received across the surface (1) within any of a plurality of fields of view, at least some of which are mutually intersecting, and
a data processing system (12,15 17), configured to determine at least one set of potential positions of objects (2,3) placed on the surface (1), based on signals from the sensor arrangement (6,7) indicating intersecting at least partially blocked fields of view, to retrieve information (19) representative of a set of pre-determined positions and to determine an intersection between the set of pre-determined positions and each set of potential positions.

11. Apparatus for obtaining user input identifying positions in two dimensions, including:
a transmitter arrangement (4,5) for directing wave energy across a surface (1) in at least two directions,
a sensor arrangement (6,7) at a periphery of the surface (1) for detecting wave energy received across the surface (1) within any of a plurality of fields of view, at least some of which are mutually intersecting, and
a data processing systern (12,15 17), configured to determine at least one set of potential positions of objects (2,3) placed on the surface (1), based on signals from the sensor arrangement (6,7) indicating intersecting at least partially blocked fields of view, to retrieve information (19) representative of a set of pre-determined positions and to determine an intersection between the set of pre-determined positions and each set of potential positions, wherein the data processing system is configured to perform a method according to claim 1.

12. Apparatus according to claim 10, wherein the transmitter arrangement (4,5) includes a first set (4) of transmitters for directing wave energy along contiguous parallel lines across the surface (1), positioned relative to the surface such that each of the first set (4) of transmitters transmits wave energy in the same direction along the contiguous parallel lines.

13. Apparatus according to claim 10, including:
first and second sets (4,5) of transmitters and
first and second sets (6,7) of receivers, the first set (4) of transmitters being arranged to direct wave energy along parallel lines in a first direction across the surface (1) and the second set (5) of transmitters being arranged to direct wave energy along parallel lines in a second direction across the surface (1),
wherein the transmitters and receivers are positioned such that only the transmitters of the first of the first and second sets (4,5) are within the field of view of the first set (6) of receivers.

14. Method of providing data for indicating positions in a user input device, including:
causing a transmitter arrangement (4,5) to direct wave energy across a surface (1) in at least two directions,
detecting, at a sensor arrangement (6,7) at a periphery of the surface (1), wave energy received across the surface within any of a plurality of fields of view, at least some of which are mutually intersecting, and, based on signals from the sensor arrangement (6,7) indicating intersecting at least partially blocked fields of view, determining a plurality of sets of positions of objects (2,3) placed on the surface (1), each set a combination of positions of a respective number of objects (2,3) resulting in the at least partial blockage of the intersecting fields of view indicated by the signals, wherein information representative of the sets of potential positions is provided to a system according to claim 10.

15. User input device for indicating positions, which user input device includes:
a transmitter arrangement (4,5) for directing wave energy across a surface (1) in at least two directions,
a sensor arrangement (6,7) at a periphery of the surface (1) for detecting wave energy received across the surface within any of a plurality of fields of view, at least some of which are mutually intersecting, and
a processing device (12) for determining potential positions of objects (2,3) placed on the surface (1), based on signals from the sensor arrangement (6,7) indicating intersecting at least partially blocked fields of view, wherein the processing device (12) is configured, based on the signals from the sensor arrangement (6,7), to determine a plurality of sets of positions of objects (2,3) placed on the surface (1), each set a combination of positions of a respective number of objects (2,3) resulting in the at least partial blockage of the intersecting fields of view indicated by the signals, and wherein the input device includes an interface for providing information representative of the sets of potential positions to a system according to claim 10.

16. Computer programme including a set of instructions capable, when incorporated in a machine-readable medium, of causing a system having information processing capabilities to perform a method according to claim 1.
